(19) United States
(12) Patent Application Publication
(10) Pub. No.: US 2013/0098873 A1
(43) Pub. Date: Apr. 25, 2013

(54) OVERHEAD ELECTRON BEAM SOURCE FOR PLASMA ION GENERATION IN A WORKPIECE PROCESSING REGION

(71) Applicants: Kartik Ramaswamy, San Jose, CA (US); Kallol Bera, San Jose, CA (US); Kenneth S. Collins, San Jose, CA (US); Shahid Rauf, Pleasanton, CA (US)

(72) Inventors: Kartik Ramaswamy, San Jose, CA (US); Kallol Bera, San Jose, CA (US); Kenneth S. Collins, San Jose, CA (US); Shahid Rauf, Pleasanton, CA (US)

(73) Assignee: Applied Materials, Inc., Santa Clara, CA (US)

(21) Appl. No.: 13/595,655

(22) Filed: Aug. 27, 2012

Related U.S. Application Data
(60) Provisional application No. 61/549,374, filed on Oct. 20, 2011.

(51) Int. Cl. H01L 21/3065; C23F 1/08

(52) U.S. Cl. 216/67; 156/345.38

(57) ABSTRACT

A plasma reactor has a main chamber for processing a workpiece in a processing region bounded between an overhead ceiling and a workpiece support surface, the reactor having an overhead electron beam source that produces an electron beam flowing into the processing region through the ceiling of the main chamber.

### CROSS-REFERENCE TO RELATED APPLICATIONS

This application claims the benefit of U.S. Provisional Application Ser. No. 61/540,374, filed Oct. 20, 2011 entitled OVERHEAD ELECTRON BEAM SOURCE FOR PLASMA ION GENERATION IN A WORKPIECE PROCESSING REGION, by Kartik Ramaswamy, et al.

### BACKGROUND

Plasma processing of a workplace such as a semiconductor wafer requires a plasma source capable of applying sufficient power to generate plasma ions from a process gas in a workpiece processing region. One challenge is that plasma generation by capacitive coupling of RE power to the process gas tends to create plasma ions with energies that increase with the RF power level. It is desirable in certain processes to minimize the plasma ion energy without necessarily sacrificing plasma ion density. In some cases, it is desirable to control the distribution of plasma ion density across the workpiece processing region.

### SUMMARY

A plasma reactor includes a main processing chamber comprising: (a) a side wall, (b) a floor and (c) a ceiling electrode insulated from the side wall and comprising plural gas flow passages; a workplace support pedestal in the chamber having a workpiece support surface facing the ceiling; an electron beam source enclosure over the ceiling and comprising a source enclosure wall having a top portion facing the ceiling and, an insulator between the source enclosure wall and the ceiling, the source enclosure wall and the ceiling being conductive. An RF source power generator is coupled to the ceiling electrode, a D.C. discharge voltage supply is coupled to the source enclosure wall, an electron beam source gas supply is coupled to the interior of the electron beam source enclosure and a workplace process gas is coupled to the interior of the electron beam source enclosure. The top portion of the source enclosure wall is displaced from the ceiling electrode by a gap, the gap having a profile whereby the gap varies as a function of location on the top portion, the profile corresponding to a desired density distribution of electron current flow through the ceiling electrode.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1 depicts a plasma reactor having a combined ceiling electron beam source and gas distribution showerhead.

FIG. 2 depicts an embodiment in which an enclosure of the ceiling electron beam source is contoured in accordance with a desired correction in electron beam density distribution.

FIG. 3 depicts an alternative contour of the electron beam source enclosure.

FIG. 4 depicts an embodiment including both an anode and en acceleration grid.

FIGS. 5 and 6 are side and top views, respectively, depicting a combined ceiling electron beam source and gas distribution showerhead having multiple radial zone.

FIGS. 7 and 8 are top and cross-sectional views, respectively, depicting a combined ceiling electron beam source and gas distribution shower head having alternate radial zones for independent electron beam generation and other radial zones for process gas distribution.

FIGS. 9, 10A and 10B are top, orthographic and cross-sectional front views, respectively, depicting a combined ceiling electron beam source, and gas distribution shower head having discrete distributed zones for independent electron beam generation and discrete distributed zones for process as distribution.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

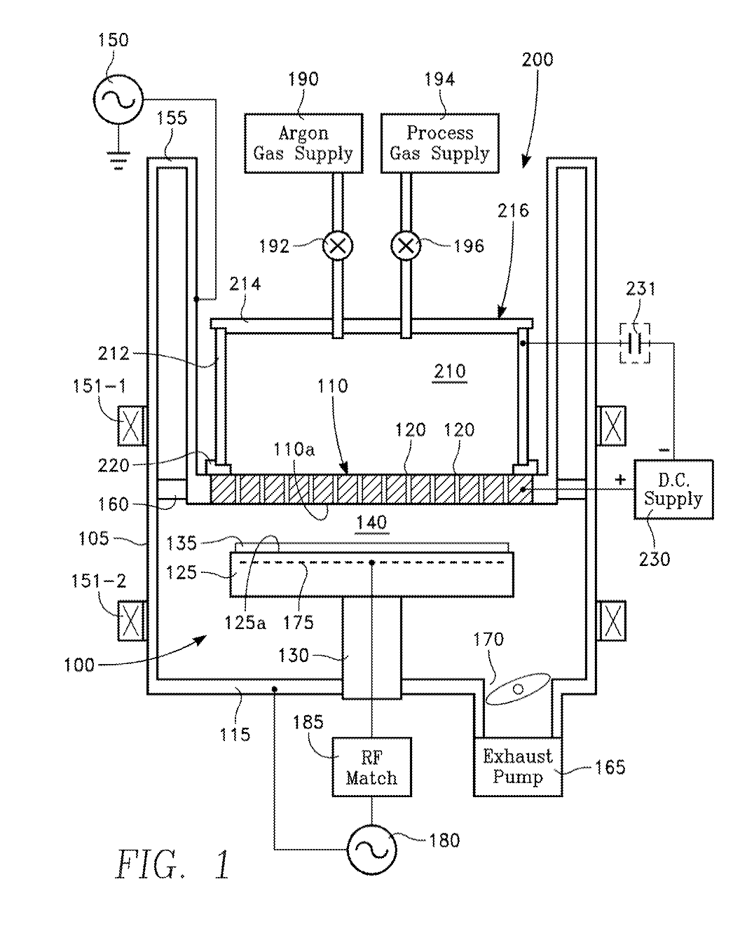

Referring to FIG. 1, a plasma reactor has a main processing chamber 100 enclosed by a cylindrical side wail 105 having an axis of cylindrical symmetry, a ceiling gas distribution plate 110 and a floor 115. The ceiling gas distribution plate 110 has an array of gas distribution orifices or passages 120 extending through the plate 110. A workpiece support pedestal 125 inside the main chamber 100 is supported on a movable shaft 130 extending through the floor 115, and has a workpiece support surface 125a on which a workpiece such as a semiconductor wafer 135 may be placed. A workpiece processing region 140 is defined between the workpiece support surface 125a and a bottom surface 110a of the ceiling gas distribution plate 110. The ceiling gas distribution plate 110 is grounded anode. Optionally, an RF power generator 150 (such as a VHF power generator) may be coupled through a coaxial RF tuning element 155 to the ceiling gas distribution plate 110. As depicted, the conductor of the coaxial RF tuning element 155. The side wall 105 forms the outer conductor of the coaxial tuning element 155. An electrically insulating ring 160 separates the side wall 105 from the ceiling gas distribution plate 110. An exhaust pump 165 is coupled to a vacuum port 170 in the floor 115. The workpiece support pedestal 130 may have an insulated electrode 175 beneath workplace support surface 125a, and en RF plasma bias bower generator 180 may be coupled through an RF impedance match circuit 185 to the insulated electrode 175.

An overhead electron beam source 200 generates electron flow through the ceiling gas distribution plate 110 into the workpiece processing region 140. The electron beam source 200 has an electron beam source enclosure 210 including a source enclosure side wall 212 and a source enclosure ceiling 214. The source enclosure side wall 212 and the source enclosure ceiling 214 are conductive and contact one another and function as the cathode of the electron beam source 200, and may be referred to collectively as the cathode 216. The electron beam source 200 produces a flow of electrons through the ceiling gas distribution plate 110 described above. The gas distribution plate 110 serves as the anode of the electron beam source 200 and may be referred to as the anode 110. An electrically insulating ring 220 separates the ceiling as distribution plate 110 tram the source enclosure side well 212. A D.C. voltage supply 230 is connected between the cathode 216 and the anode 110, the negative supply terminal of the D.C. voltage supply 230 being connected to the cathode 216.

A gas particularly suited for producing electrons, e.g., an electropositive gas such as Argon, is furnished into the interior of the source, enclosure 210 from a first gas supply 190 through a valve 192. A process gas suited for carrying out a plasma process on the workpiece 135 is furnished into the interior of the source enclosure 210 from a second gas supply 194 through valve 196.

Argon gas and/or process gas in the source enclosure 210 is ionised by a D.C. discharge supported by the D.C. voltage supply 230. This produces electron flow through the gas flow passages 120 in the anode 110. Optionally, the process gas from the second gas supply 194 is drawn through the gas flow passages 120 in the anode 110 into the workpiece processing region 140, where it is ionized by power from the RF generator 150 or 190, to form a plasma for processing the workpiece 135. Plasma density in the workpiece processing region 140 is enhanced by the electrons flowing through the anode 110 from the electron beam source 200. Plasma density in the workpiece processing region 140 therefore may be increased by increasing the electron current (electron beam) flowing through the anode 110 into the workpiece processing region 140, by either increasing the voltage furnished by the D.C. voltage source 230, or by increasing the gas flow rate of the electropositive gas (Argon) from the first gas supply 190, or both. An advantage is that plasma ion density may be increased without increasing the power level of the RF power generator 150 or 130, thus avoiding a proportionate increase in plasma ion energy in workpiece processing region 140.

Plasma confinement magnets 151-1 and 151-2, which may be electro-magnets driven by a D.C. current, confine the electron beam flowing from the source 200 reducing divergence in the electron beam path. The plasma inside the source housing 200 may be continuous or it may be pulsed. Pulsing may be performed by pulsing the voltage source 230 or by connecting an optional capacitor 231 in series between the cathode 216 and the D.C. voltage source 230. The capacitor 231 charges until its voltage reaches a D.C. discharge breakdown voltage, and a plasma discharge occurs, until the capacitor 231 is discharged, and the process repeats itself.

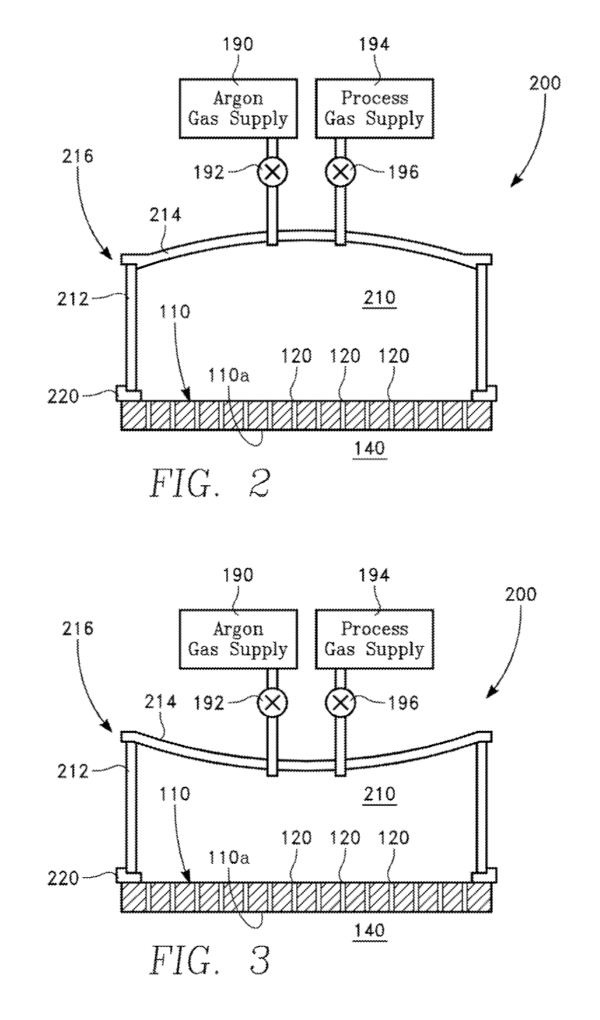

Radial distribution of electron density in the electron current flowing through the anode 110 may be adjusted by adjusting the shape of the source enclosure ceiling 214. For example, in the embodiment of FIG. 2, the source enclosure ceiling 214 is center high and edge low. As a result, the gap between the source enclosure ceiling 214 and the anode 110 is center high and edge low, which increases electron density at the center relative to electron density at the edge, thereby changing the radial distribution of electron current through the anode 110. This produces a corresponding increase in plasma ion density at the center of the workpiece processing region 140 relative to plasma ion density at the edge of the workpiece processing region 140. Such a change is useful in cases in which the reactor exhibits a center-low plasma ion distribution in absence of profiling of the source enclosure ceiling 214.

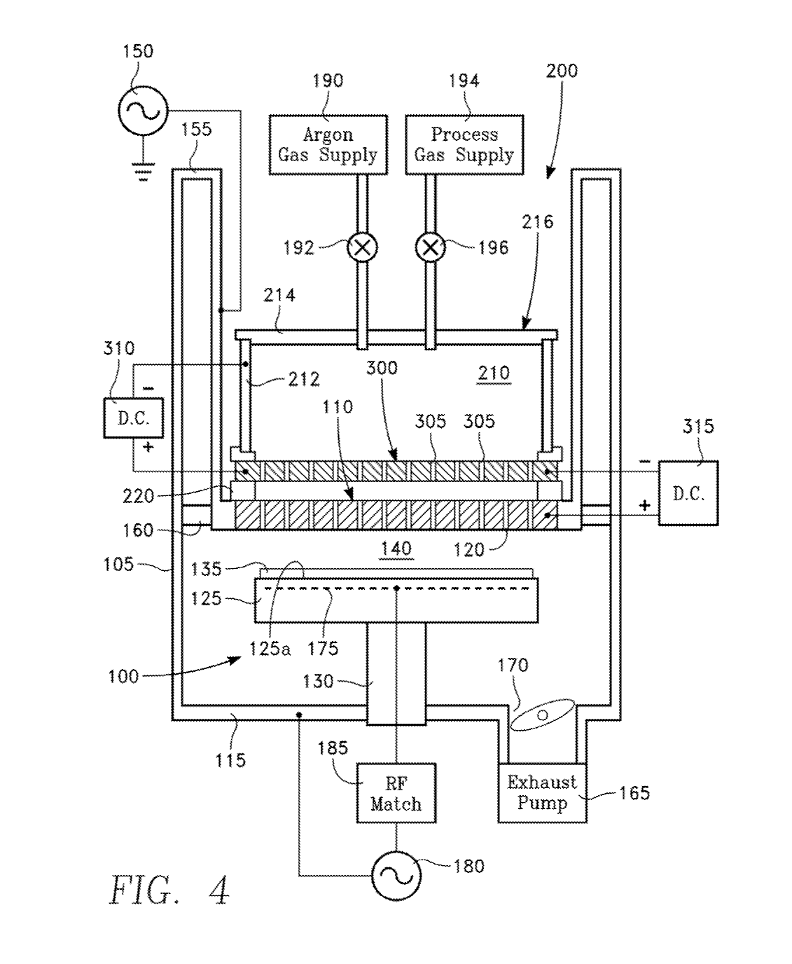

As another example, in the embodiment of FIG. 3, the source enclosure ceiling 214 is center low and edge high. The gap between the source enclosure ceiling 214 and the anode 110 is center low and edge high, which decreases electron density at the center relative to electron density at the edge, thereby changing the radial distribution of electron current through the anode 110. This produces a corresponding decrease in plasma ion density at the center of the workpiece processing region 140 relative to plasma ion density at the edge of the workplace processing region 140. Such a change is useful in cases in which the reactor exhibits a center-high plasma ion distribution in absence of profiling of the source enclosure ceiling 214.

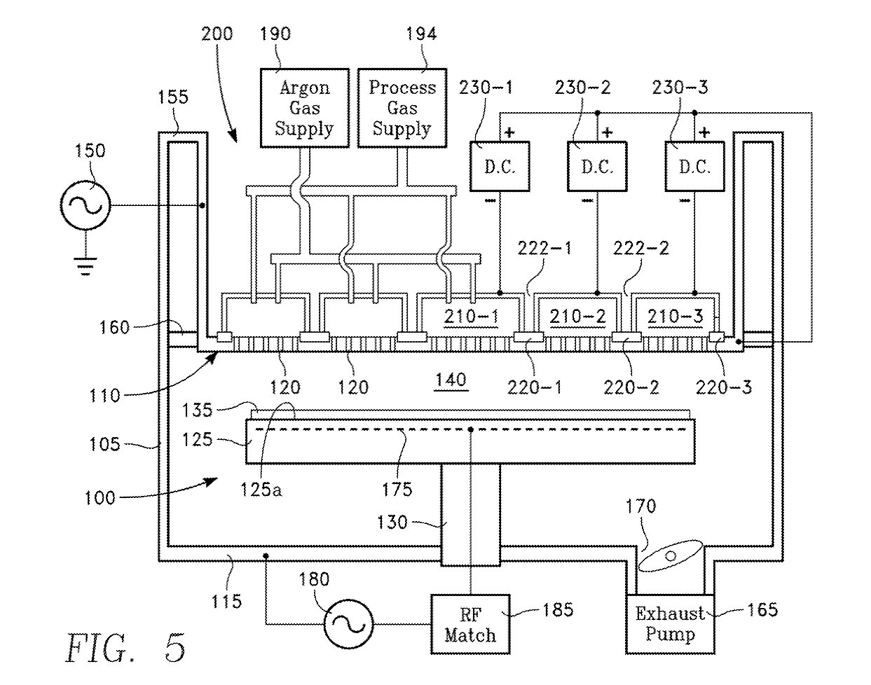

FIG. 4 depicts a modification of the embodiments of FIG. 1, 2 or 3, which an extraction grid 300 is added, the extraction grid 300 being placed above the anode 110. The extraction grid 300 has plural gas flow passages 305 the may be in registration, with the gas flow passages 120 of the anode 110. In the embodiment of FIG. 4, a D.C. discharge voltage supply 310 is connected between the cathode 214 and the extraction grid 300, with the positive terminal of the D.C. discharge voltage supply being connected to the extraction, grid 300. A D.C. acceleration voltage supply 315 is connected between the extraction grid 300 and the anode 110, with the positive terminal of the D.C. acceleration voltage supply being connected to the anode 110. The D.C. discharge voltage supply 310 may have a supply voltage in the range of 50 volts to 500 volts. The D.C. acceleration voltage supply 315 may have a supply voltage in a range from 20 volts to 20 kV, for example. FIG. 4 shows that the extraction grid 300 overlies the anode 110. Each of the embodiments described may include this feature, although the descriptions do not specifically refer to this feature.

The electron beam energy, primarily determined by the acceleration voltage, can range, from 20 eV to 2000 eV. The collision cross-sections for different processes depend on electron energy. The inelastic processes and transport properties are decided by the collision cross-sections. For example, in Ar plasma, the threshold of excitation is 11.55 eV while ionization threshold is 15.76 eV. As the electron energy increases to 30 eV and beyond, ionization cross-section becomes larger and larger than excitation cross-section. As a result Ar+ ion density becomes higher than Ar* density at higher energy. With use of different electron energy, one can get different ratios of ion to excited species for process control. Using different acceleration voltage, the plasma species and the plasma process can be controlled with time at different locations as needed.

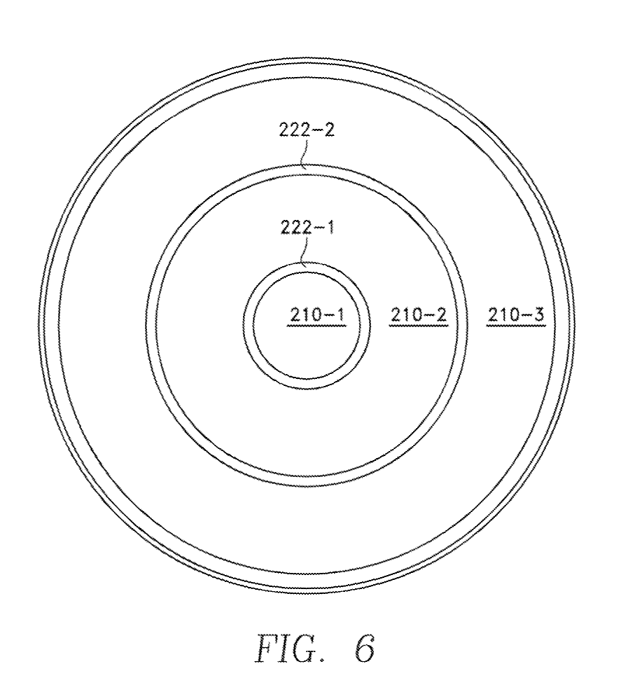

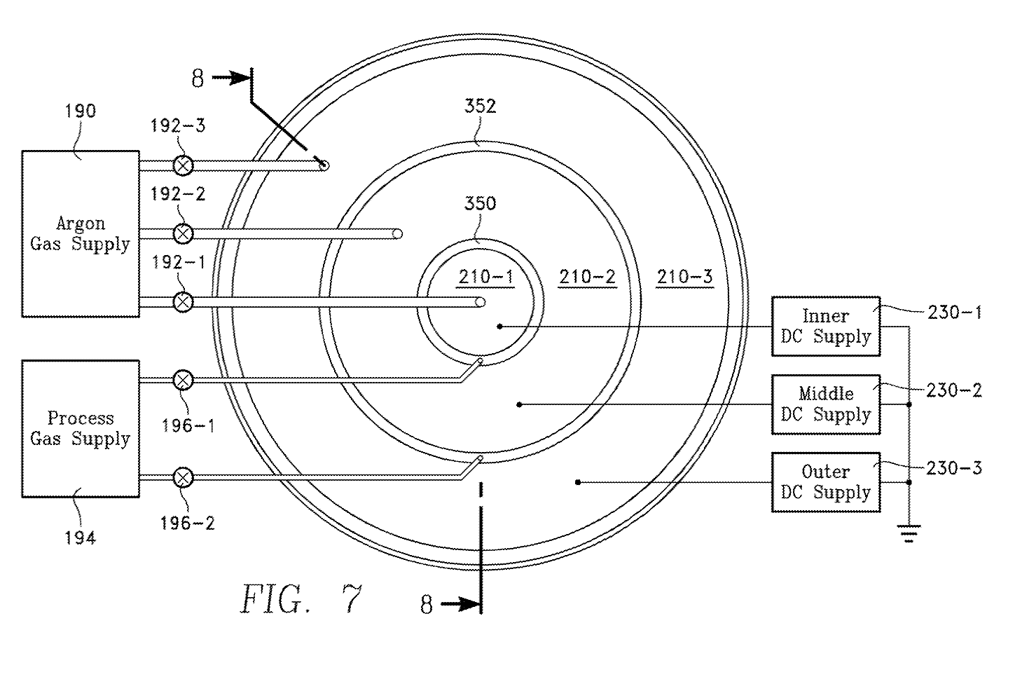

FIGS. 5 and 6 depict an embodiment in which the electron beam source 200 has separate concentric annular electron beam source enclosures 210-1, 210-2, 210-3 connected to independently adjustable D.C. voltage supplies 230-1, 230-2, 230-3. Concentric insulator rings 220-1, 220-2 and 220-3 provide electrical separation of the electron beam source enclosures 210-1, 210-2, 210-3 from the anode 110 and from each other, and define annular spaces 222-1, 222-2 between the adjacent enclosures. The argon gas supply 190 and the process gas supply 194 are coupled to deliver gas into each of the electron beam source enclosures 210-1, 210-2 and 210-3. The anode 110 may include the array of gas flow passages 120 for the flow of Argon, process gas and electrons into the process region 140 below the anode 110. The radial distribution of electron current in the electron beam is adjusted by separately adjusting the voltage levels of the D.C. voltage supplies 230-1, 230-2, 230-3.

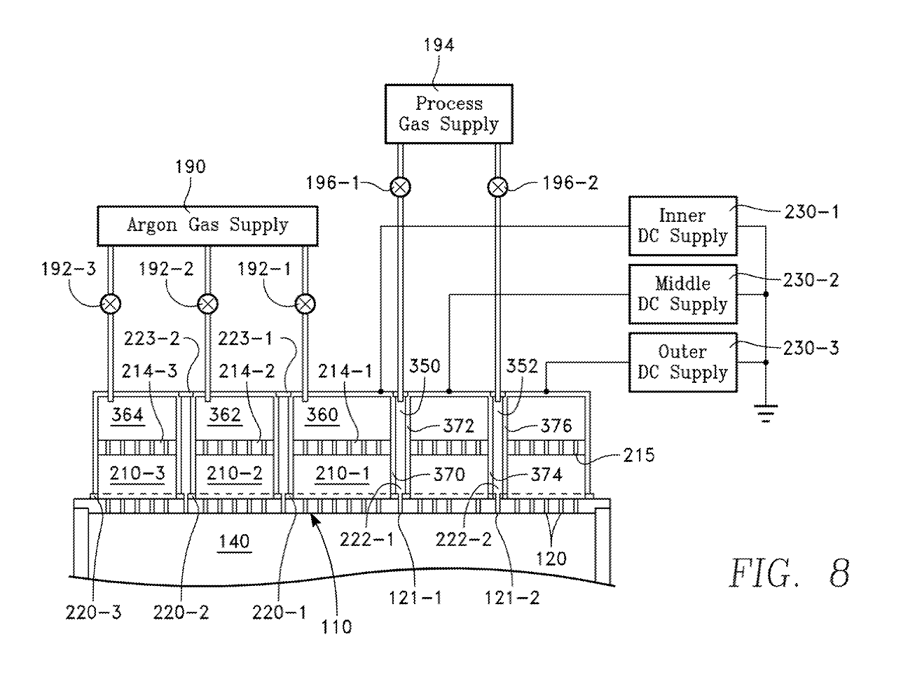

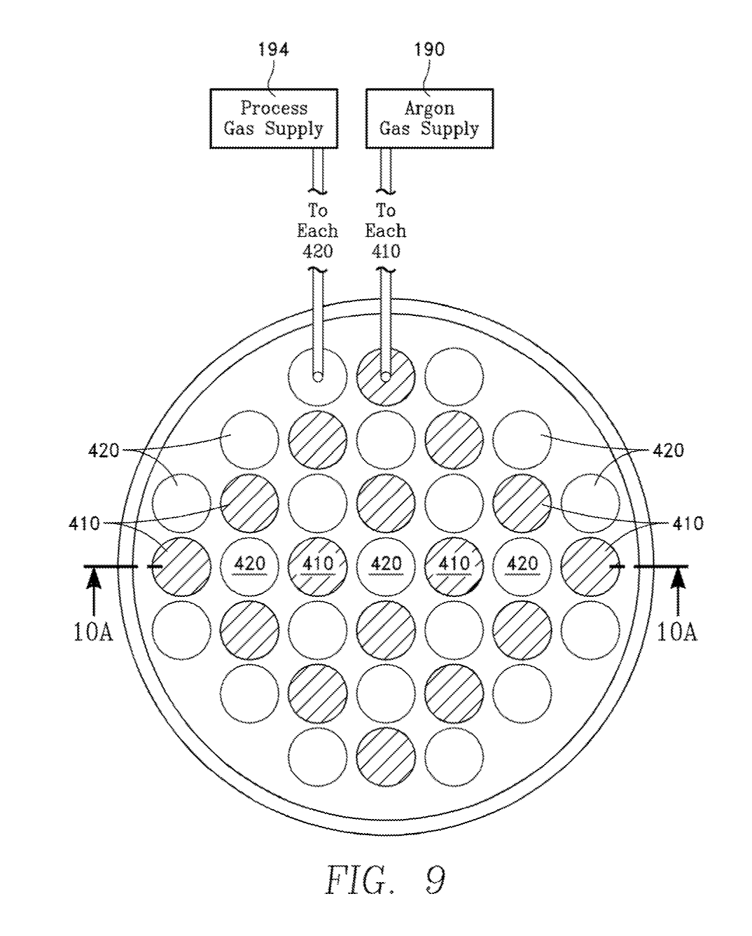

FIGS. 7 and 8 depict an embodiment in which the process gas supply 194 is coupled through separate valves 196-1, 196-2 to annular process gas conduits 350 and 352 defined by the spaces 222-1 and 222-2. As shown in FIG. 8, concentric annular conduits 360, 362, 364 for the electron beam source gas (Argon) and the concentric annular process gas conduits 350, 352 are defined by concentric annular walls 370, 372, 374, 376 and 378. Concentric insulator rings 220-1, 220-2 and 220-3 separate the annular conduits 360, 362 and 364 from the anode 110. Gas flow paths from the annular process gas conduits 350 and 352 into the processing region 140 are provided by concentric annular gas flow openings 121-1 and 121-2, respectively. The concentric annular gas flow openings 121-1 and 121-2 extend through the insulator rings 220-1 and 220-2, respectively, and through the anode 110. The annular process gas conduits 350 and 352 are enclosed at their upper ends by concentric insulator rings 223-1 and 223-2 respectively. Optionally, if it is desired to apply an acceleration voltage, then source enclosure ceilings 214-1, 214-2 and 214-3 may be provided and connected to an acceleration voltage source (such as the acceleration voltage source 315 of FIG. 4, not shown in FIG. 8). Each of the source enclosure, ceilings 214-1, 214-2 and 214-3 may have an array of gas hole passages 215 that permit the electron beam source gas (Argon) to flow through them into the interiors of the source enclosures 210-1, 210-2, 210-3. If no acceleration voltage is to be applied in this manner, then the source enclosure ceilings 214-1, 214-2 and 214-3 may be eliminated. As shown in FIG. 8, the annular walls of the electron be source enclosures 210-1, 210-2 and 210-3 are insulated from one another and from the anode 110 by respective insulator rings 220. As shown in FIG. 7, electron beam source gas flow into each source enclosure 210-1, 210-2, 210-3 is controlled independently by a respective valve 192-1, 192-2, 192-3. Radial distribution of electron current through the anode 110 (which affects distribution of plasma ion density in the workpiece processing region 140) may be controlled by separate adjustment of any one or a combination of the following: (a) the D.C. voltage supplies 230-1, 230-2, 230-3, and (b) the gas flow valves 192-1, 192-2, 192-3. The gas flow valves 196-1 and 196-2 may be separately adjusted to affect plasma density distribution in the processing region 140 by controlling distribution of the process gas.

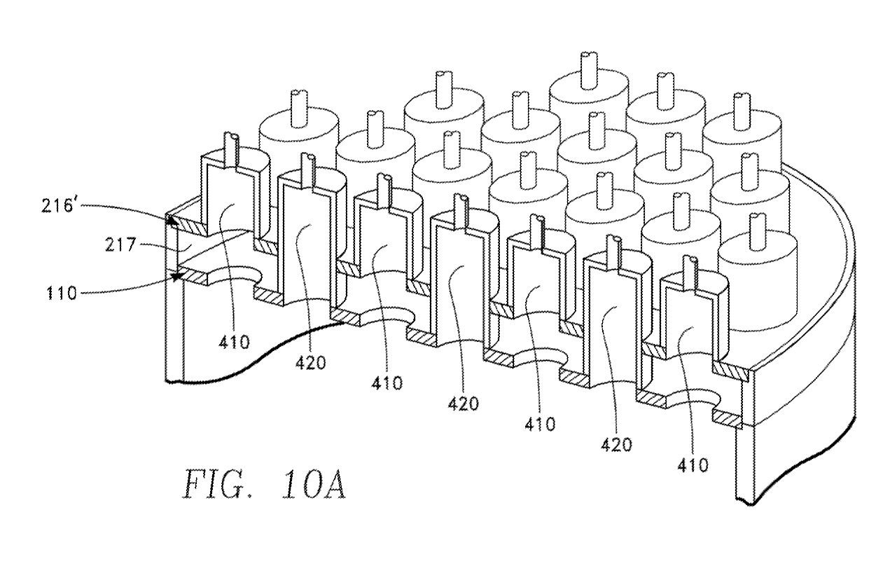

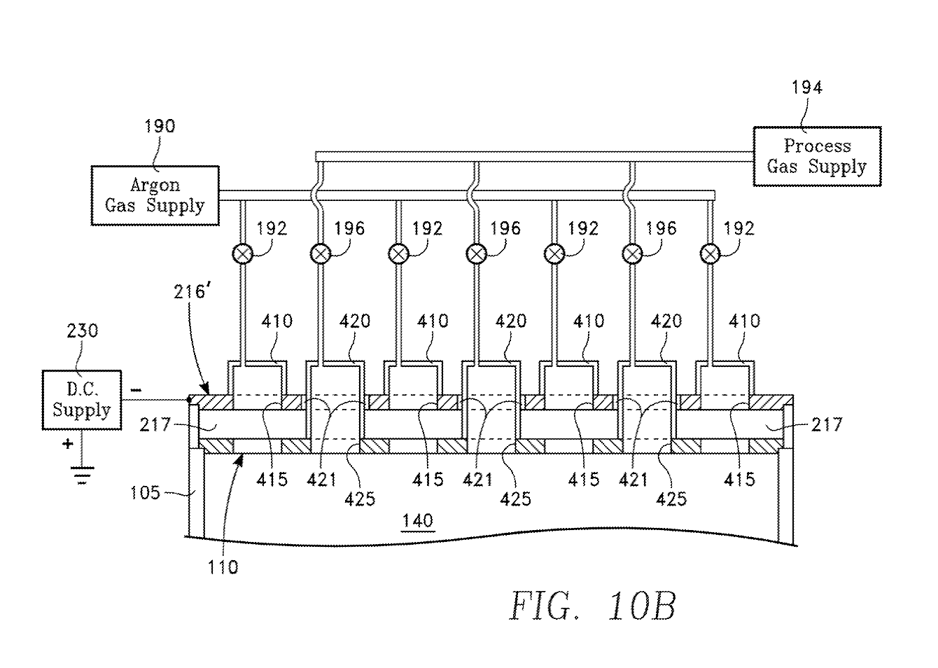

FIGS. 9, 10A and 10B depict an embodiment having a distributed array of discrete, elongate electron beam source conduits 410, interlaced with a distributed array of discrete elongate process gas flow conduits 420, A cathode 216′ is arrange parallel to the anode 110, defining a D.C. plasma discharge region 217 between them. The source conduits 410, extend to the cathode 216′. Respective openings 415 in the cathode 216′ admit electron beam source gas from the respective source conduits 410, into the D.C. plasma discharge region 217. The process gas flow conduits 420, extend through the cathode 216′, bypassing the D.C. plasma discharge region 217. Respective insulating rings 421 depicted in FIG. 10B provide: electrical separation between the cathode 216′ and the process gas flow conduits 420. Respective openings 425 in the anode 110 admit process gas from the process gas flow conduits 420, into the process region 140 below. In one embodiment, the openings 415 in the cathode 216′ may be replaced by an array of gas flow orifices or holes. In one embodiment, the openings 425 in the cathode 110 may be replaced by an array gas flow orifices or holes.

Each discrete source conduit 410, has its own cylindrical side wall and ceiling. The discrete source conduits 410, may be distributed in any desirable patter, so that distribution of electron beam density may be adjusted in a radial direction or along a non-radial direction (e.g., along a circumferential direction. The process gas supply 194 is coupled through respective valves 196 to the respective process gas flow conduit 420, and so forth.

In the embodiment of FIG. 1, a field emitter may be employed in the electron beam source 200 as the electron source. This may be instead of, or in addition to, the use of an electron beam source gas (e.g., argon) in a plasma discharge as the electron source. The field emitter may be a carbon-nano tube inside the source 200, or silicon or velvet material, and is held at a high negative voltage.

In the embodiment of FIG. 1, the top surface of the anode 110 (i.e., the surface facing the interior of the source housing 210 may have small peaks (not shown) formed between adjacent gas flow passages 120. Each of the small peaks faces the interior of the source housing 210 and serving as a focusing lens.

In the above-described embodiments, the distance or gap between the anode 110 and the surface of the workpiece support surface of the pedestal 125 may be selected to be in a large range, between 0.5 inches and 5.0 inches. The electron beam emerges from the anode 110 toward the workpiece, as described above. An advantage of the smaller value of the gap (e.g., 0.5 inch to inches, or in a range, of less than 5 inches) is that the electron energy in the electron beam can be very small (e.g., 20 ev for the smaller gap values). In fact, the electron energy may be controlled or varied within in a very large range (e.g., 20 ev to 2,000 ev). A method of controllably varying the ratio of excited or dissociated species density to plasma ion density in the process region 140 is to vary the electron energy within the range of 20 ev to 2,000 ev. This feature can control or vary ratio of excited or dissociated species density to plasma ion density in the process region 140 within a very large range, a significant advantage. In the embodiments of FIGS. 1 and 10B, the electron energy is controlled or varied by varying or controlling the voltage of the DC voltage supply 230. In the embodiment of FIG. 4, the electron energy is controlled or varied by varying or controlling the voltage of the DC voltage supply 315. In the embodiments of FIGS. 5 and 8, the electron energy is controlled or varied by varying or controlling the voltage of the DC voltage supplies 230-1, 230-2 and 230-3, which controls the ratio of excited or dissociated species density to plasma ion density in the different concentric zones of the process region.

While the foregoing is directed to embodiments of the present invention, other and further embodiments of the invention may be devised without departing from the basic scope thereof, and the scope thereof is determined by the claims that follow.

What is claimed is:

1. A plasma reactor comprising:
a main processing chamber comprising: (a) a side wall, (b) a floor and (c) a ceiling electrode insulated from said side wall and comprising plural gas flow passages;
a workpiece support pedestal in said chamber having a workpiece support surface facing said ceiling;
an electron beam source enclosure overlying said ceiling and comprising a source enclosure wall having a top portion facing said ceiling, and an insulator between said source enclosure wall and said ceiling, said source enclosure wall and said ceiling being conductive;
an RF source power generator coupled to said ceiling electrode, a D.C. discharge voltage supply coupled to at least one of said ceiling and said source enclosure wall, an electron beam source gas supply coupled to the interior of said electron beam source enclosure and a workpiece process gas coupled to the interior of said electron beam source enclosure; and
said top portion of said source enclosure wall being displaced from said ceiling electrode by a gap, said gap having a profile whereby said gap varies as a function of location on said to portion, said profile corresponding to a desired density distribution of electron current flow through said ceiling electrode.

2. The plasma reactor of claim 1 wherein said profile is radially symmetrical.

3. The plasma reactor of claim 2 wherein said top portion has one of a convex shape or a concave shape.

4. The plasma reactor of claim 1 wherein said desired density distribution of electron current flow through said ceiling electrode is complementary to a non-uniformity of plasma ion distribution over said workpiece support surface in absence of an electron current through said ceiling electrode.

5. The plasma reactor of claim 1 further comprising:
a first plasma confinement magnet concentric with and surrounding said electron beam source enclosure.

6. The plasma reactor of claim 5 further comprising:
a second plasma confinement magnet concentric with and surrounding said main processing chamber and being coaxial with said first plasma confinement magnet.

7. A plasma reactor comprising:
a main processing chamber comprising a side wall, a floor and a ceiling electrode insulated from said side wall and comprising plural gas flow passages;
a workpiece support pedestal in said chamber having a workpiece support surface facing said ceiling;
plural concentric electron beam source enclosures overlying said ceiling and electrically insulated from one another, said plural source enclosures comprising respective source enclosure walls having respective annular portions and respective top portions facing said ceiling, said annular portions being insulated from said ceiling electrode;
plural D.C. discharge voltage sources coupled to respective ones of said top portions, an electron beam source gas supply coupled to the interiors of said plural source enclosures and a workpiece process gas supply coupled to furnish process gas into said main processing chamber; and
an RF source power generator coupled to said ceiling electrode.

8. The plasma reactor of claim 7 further comprising respective valves coupling said electron beam source gas supply to respective ones of said plural electron beam source enclosures.

9. The plasma reactor of claim 7 wherein:
said respective annular portions of said source enclosure walls comprise a pair of annular concentric walls separating respective ones of the plural concentric electron beam source enclosures.

10. The plasma reactor of claim 7 wherein said plural D.C. discharge voltage sources are separately adjustable for configuring electron density distribution.

11. The plasma reactor of claim 7 wherein:
said annular portions of said source enclosure walls comprise respective pairs of annular walls defining respective annular gas flow conduits isolated from interiors of said plural concentric electron beam source enclosures; and
said workplace process gas supply is coupled to said respective annular gas flow conduits.

12. The plasma reactor of claim 7 further comprising respective valves coupling said workplace process gas supply to respective ones of said respective annular gas flow conduits.

13. A plasma reactor comprising:
a main processing chamber comprising a side wall defining an axis of symmetry, a floor and a ceiling electrode insulated from said side wall and comprising plural as flow passages;
a workpiece support pedestal in said chamber having a workpiece support surface facing said ceiling;
an electron beam source gas supply and a workpiece process gas supply;
plural electron beam source enclosures overlying said ceiling, said plural source enclosures comprising respective axial side walls and respective radial top portions facing said ceiling, said source enclosures being insulated from said ceiling electrode, said electron beam source gas supply being coupled to each of said plural electron be source enclosures;
plural workpiece gas flow conduits extending axially and being separate from said plural electron beam source enclosures and having respective top openings coupled to said workpiece process gas supply and respective bottom openings facing said ceiling electrode;
plural D.C. discharge voltage sources coupled to respective ones of said top portions; and
an RF source power generator coupled to said ceiling electrode.

14. The plasma reactor of claim 13 further comprising respective valves coupling said electron beam source gas supply to respective ones of said plural electron beam source enclosures.

15. The plasma reactor of claim 13 wherein said plural D.C. discharge voltage sources are separately adjustable for configuring electron density distribution.

16. The plasma reactor of claim 15 further comprising respective valves coupling said workpiece process gas supply to respective ones of said respective gas flow conduits.

17. A method of processing a workpiece in a plasma reactor comprising:
placing the workplace on a workpiece support surface of the reactor, the reactor having (A) a ceiling electrode with plural gas flow channels facing and overlying the workplace support surface, and (B) an electron beam source enclosure wall insulated from the ceiling electrode and enclosing an electron bean source chamber overlying the ceiling electrode;
supplying an electron beam source gas into the electron beam source chamber and supplying a workpiece processing gas into a process zone between the ceiling electrode and the workpiece;
coupling a D.C. discharge voltage supply to at least one of the ceiling electrode and the electron beam source enclosure wall to produce an electron beam; and
controlling the ratio of excited or dissociated species density to plasma ion density in said process region by setting the voltage of said D.C. discharge voltage supply to establish an electron energy of said electron beam in a range of 20 ev to 2000 ev.

18. The method of claim 17 further comprising:
setting a gap between said ceiling electrode and said workpiece to a distance not exceeding 5 inches.

19. The method of claim 18 wherein said distance is in a range of 0.5 inch to 5.0 inches.
